(19) United States
(12) Patent Application Publication
(10) Pub. No.: US 2024/0385538 A1
(43) Pub. Date: Nov. 21, 2024

(54) INFORMATION COLLECTION SYSTEM, INSPECTION SUBSTRATE, AND INFORMATION COLLECTION METHOD

(71) Applicant: Tokyo Electron Limited, Tokyo (JP)

(72) Inventors: Junnosuke Maki, Koshi City (JP); Masato Hayashi, Koshi City (JP); Nobuyuki Sata, Koshi City (JP); Ryo Konishi, Koshi City (JP)

(21) Appl. No.: 18/662,204

(22) Filed: May 13, 2024

(30) Foreign Application Priority Data
May 15, 2023 (JP) 2023-079893

(51) Int. Cl. G03F 7/00; G03F 7/26

(52) U.S. Cl. CPC G03F 7/7085; G03F 7/26; G03F 7/70508

(57) ABSTRACT

An information collection system is configured to acquire information on a substrate processing apparatus having a holder configured to hold a substrate and a functional member located on a rear surface side of the substrate when the substrate is held by the holder. The information collection system includes a main body having a bottom surface allowed to be held by the holder; a radiator fixed to the main body, and configured to radiate a measurement wave to the functional member from obliquely above; a detector fixed to the main body, and configured to detect a response resulting from a radiation of the measurement wave from the radiator; and a calculator configured to acquire information on a distance between the main body and the functional member based on the response detected by the detector.

### CROSS-REFERENCE TO RELATED APPLICATION

This application claims the benefit of Japanese Patent Application No. 2023-079893 filed on May 15, 2023, the entire disclosure of which is incorporated herein by reference.

### TECHNICAL FIELD

The various aspects and embodiments described herein pertain generally to an information collection system, an inspection substrate, and an information collection method.

### BACKGROUND

Patent Document 1 discloses a substrate processing apparatus for processing a substrate. This substrate processing apparatus has a ring member that is provided in an annular shape at a position facing a rear surface of the substrate held by a substrate holder and has a diameter smaller than that of the substrate.
Patent Document 1: Japanese Patent Laid-open Publication No. 2020-013931

### SUMMARY

In an exemplary embodiment, an information collection system is configured to acquire information on a substrate processing apparatus having a holder configured to hold a substrate and a functional member located on a rear surface side of the substrate when the substrate is held by the holder. The information collection system includes a main body having a bottom surface allowed to be held by the holder; a radiator fixed to the main body, and configured to radiate a measurement wave to the functional member from obliquely above; a detector fixed to the main body, and configured to detect a response resulting from a radiation of the measurement wave from the radiator; and a calculator configured to acquire information on a distance between the main body and the functional member based on the response detected by the detector.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic diagram illustrating an example of a substrate processing system;

FIG. 2 is a schematic diagram illustrating an example of the substrate processing system;

FIG. 3 is a schematic diagram illustrating a liquid processing device;

FIG. 4 is a diagram illustrating an example of a relationship between an inspection wafer, an information collection device, and a controller;

FIG. 5 is a diagram illustrating an example of a configuration of a measurer in the inspection wafer;

FIG. 6A and FIG. 6B are diagrams illustrating an example of the configuration of the measurer;

FIG. 7 is a diagram illustrating an example of a hardware configuration of a controller, an information collection device, and an inspection wafer;

FIG. 8 is a diagram for explaining an example of a measurement method of measuring a distance;

FIG. 9 is a graph showing an example of a model for measuring the distance;

FIG. 10A is a flowchart illustrating an example of the measurement method and FIG. 10B presents an example of a taken image;

FIG. 11A is a flowchart illustrating an example of the measurement method and FIG. 11B presents an example of a taken image.

FIG. 12A is a flowchart illustrating an example of the measurement method and FIG. 12B presents an example of a taken image; and

FIG. 13 is a schematic diagram illustrating a measurement location and a plurality of measurement points.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, an exemplary embodiment of the present disclosure will be described with reference to the accompanying drawings. In the following description, same parts or parts having same functions will be assigned same reference numerals, and redundant description thereof will be omitted. In some of the accompanying drawings, there may be used a rectangular coordinate system defined by an X-axis, a Y-axis and a Z-axis. In the following exemplary embodiment, the Z-axis direction corresponds to a vertical direction, and the X-axis and Y-axis directions correspond to horizontal directions.

### Substrate Processing System

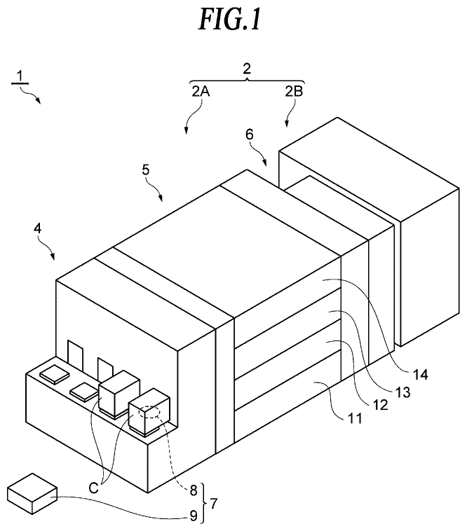

FIG. 1 schematically illustrates a substrate processing system according to an exemplary embodiment. The substrate processing system 1 shown in FIG. 1 is a system configured to perform, on a workpiece W, formation of a photosensitive film, exposure of the photosensitive film, and development of the photosensitive film. The workpiece W as a processing target is, for example, a silicon wafer. The workpiece W (substrate) may be of a circular shape. The workpiece W may be a glass substrate, a mask substrate, an FPD (Flat Panel Display), or the like. The photosensitive film is, for example, a resist film.

The substrate processing system 1 (information collection system) has a function of collecting information regarding the substrate processing apparatus in addition to a function of performing a substrate processing including the formation of the photosensitive film. The substrate processing system 1 is equipped with a substrate processing apparatus 2 and an information collection system 7.

The substrate processing apparatus 2 includes a coating and developing apparatus 2A, an exposure apparatus 2B, and a controller 100. The exposure apparatus 2B is configured to expose a resist film (photosensitive film) formed on the workpiece W. To elaborate, the exposure apparatus 2B radiates an energy beam to an exposure target portion of the resist film by an immersion exposure method or the like. The coating and developing apparatus 2A (substrate processing apparatus) is configured to perform a processing of forming the resist film by coating a resist (chemical liquid) on a surface of the workpiece W prior to the exposure processing by the exposure apparatus 2B, and is also configured to perform a developing processing for the resist film after being subjected to the exposure processing by the exposure apparatus 2B.

### (Substrate Processing Apparatus)

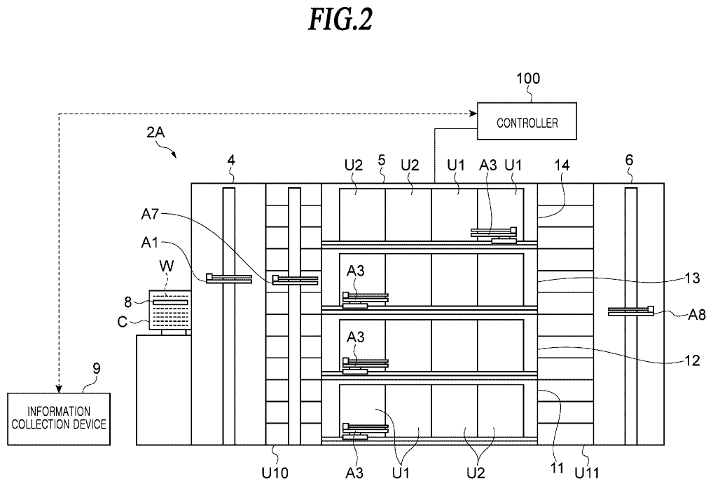

Referring to FIG. 1 and FIG. 2, a configuration of the coating and developing apparatus 2A as an example of a substrate processing apparatus will be explained. As depicted in FIG. 1 and FIG. 2, the coating and developing apparatus 2A is equipped with a carrier block 4, a processing block 5, and an interface block 6.

The carrier block 4 is configured to carry the workpiece W into/from the coating and developing apparatus 2A. For example, the carrier block 4 is configured to support a plurality of carriers C for workpieces W, and incorporates therein a transfer device A1 including a delivery arm. Each carrier C accommodates therein, for example, a multiple number of circular workpieces W. The transfer device A1 is configured to take out the workpiece W from the carrier C, hand the workpiece W over to the processing block 5, receive the workpiece W from the processing block 5 and return the workpiece W back into the carrier C. The processing block 5 includes a plurality of processing modules 11, 12, 13 and 14.

The processing module 11 incorporates therein a liquid processing device U1, a heat treatment device U2 and a transfer device A3 configured to transfer the workpiece W to these devices. The processing module 11 is configured to form a bottom film on a front surface of the workpiece W by using the liquid processing device U1 and the heat treatment device U2. The liquid processing device U1 is configured to coat a processing liquid configured to form the bottom film on the workpiece W. The heat treatment device U2 is configured to perform various kinds of heat treatments required to form the bottom film.

The processing module 12 incorporates therein a liquid processing device U1, a heat treatment device U2, and a transfer device A3 configured to transfer the workpiece W to these devices. The processing module 12 is configured to form a resist film on the bottom film by using the liquid processing device U1 and the heat treatment device U2. The liquid processing device U1 is configured to coat, on the bottom film, a processing liquid (resist) configured to form the resist film. The heat treatment device U2 is configured to perform various kinds of heat treatments required to form the resist film.

The processing module 13 incorporates therein a liquid processing device U1, a heat treatment device U2, and a transfer device A3 configured to transfer the workpiece W to these devices. The processing module 13 is configured to form a top film on the resist film by using the liquid processing device U1 and the heat treatment device U2. The liquid processing device U1 is configured to coat, on the resist film, a processing liquid configured to form the top film. The heat treatment device U2 is configured to perform various kinds of heat treatments required to form the top film.

The processing module 14 incorporates therein a liquid processing device U1, a heat treatment device U2 and a transfer device A3 configured to transfer the workpiece W to these devices. The processing module 14 is configured to perform, by using the liquid processing device U1 and the heat treatment device U2, a developing processing on the resist film after being subjected to an exposure processing as well as a heat treatment required for the developing processing. The liquid processing device U1 is configured to perform the developing processing for the resist film by coating a developing liquid on the front surface of the workpiece W after being subjected to the exposure processing and then rinsing it away with a rinse liquid. The heat treatment device U2 is configured to perform the various kinds of heat treatments required for the developing processing. Specific examples of these heat treatments include a heat treatment (PEB: Post Exposure Bake) before developing, a heat treatment (PB: Post Bake) after developing, and so forth.

Within the processing block 5, a shelf section U10 is provided near the carrier block 4. The shelf section U10 is partitioned into a multiple number of cells arranged in a vertical direction. A transfer device A7 including an elevating arm is provided near the shelf section 10. The transfer device A7 is configured to move the wafer W up and down between the cells of the shelf section U10.

Within the processing block 5, a shelf section U11 is provided near the interface block 6. The shelf section U11 is partitioned into a multiple number of cells arranged in the vertical direction.

The interface block 6 is configured to deliver the workpiece W into/from the exposure apparatus 2B. By way of example, the interface block 6 incorporates therein a transfer device A8 including a delivery arm, and is connected to the exposure apparatus 2B. The transfer device A8 is configured to hand the workpiece W placed in the shelf section U11 over to the exposure apparatus 2B. The transfer device A8 is also configured to receive the workpiece W from the exposure apparatus 2B and return it back into the shelf section U11.

A control over the above-described coating and developing apparatus 2A is performed by the controller 100. The controller 100 retains information regarding a processing sequence for performing a processing of the workpiece W in the coating and developing apparatus 2A, and controls the individual components such that the workpiece W is carried into the coating and developing apparatus 2A and subjected to a preset substrate processing. Further, the controller 100 has a function of transmitting and receiving the information to and from the information collection system 7.

The processing of the workpiece W performed in the coating and developing apparatus 2A will be discussed. The controller 100 controls the coating and developing apparatus 2A to perform the processing on the workpiece W in the following sequence, for example. First, the controller 100 controls the transfer device A1 to transfer the workpiece W in the carrier C to the shelf section U10, and controls the transfer device A7 to place this workpiece W in the cell for the processing module 11.

Then, the controller 100 controls the transfer device A3 to transfer the workpiece W of the shelf section U10 to the liquid processing device U1 and the heat treatment device U2 in the processing module 11. Additionally, the controller 100 controls the liquid processing device U1 and the heat treatment device U2 to form a bottom film on a front surface of the workpiece W. Thereafter, the controller 100 controls the transfer device A3 to return the workpiece W having the bottom film formed thereon back into the shelf section U10, and controls the transfer device A7 to place this workpiece W in the processing module 12.

Subsequently, the controller 100 controls the transfer device A3 to transfer the workpiece W of the shelf section U10 to the liquid processing device U1 and the heat treatment device U2 in the processing module 12. The controller 100 controls the liquid processing device U1 and the heat treatment device U2 to form a resist film on the bottom film of the workpiece W. Thereafter, the controller 100 controls the transfer device A3 to return the workpiece W back into the shelf section U10, and transfers the transfer device A7 to place this workpiece W in the cell for the processing module 13.

Thereafter, the controller 100 controls the transfer device A3 to transfer the workpiece W of the shelf section U10 to the liquid processing device U1 and the heat treatment device U2 in the processing module 13. Furthermore, the controller 100 controls the liquid processing device U1 and the heat treatment device U2 to form a top film on the resist film of the workpiece W. Thereafter, the controller 100 controls the transfer device A3 to transfer the workpiece W to the shelf section U11.

Next, the controller 100 controls the transfer device A8 to send the workpiece W accommodated in the shelf section U11 to the exposure apparatus 2B. Then, in the exposure apparatus 2B, an exposure processing is performed on the resist film formed on the workpiece W. Thereafter, the controller 100 controls the transfer device A8 to receive the workpiece W after being subjected to the exposure processing from the exposure apparatus 2B and place the received workpiece W in the cell for the processing module 14 in the shelf section U11.

Subsequently, the controller 100 controls the transfer device A3 to transfer the workpiece W of the shelf section U11 to the heat treatment device U2 of the processing module 14. Then, the controller 100 controls the liquid processing device U1 and the heat treatment device U2 to perform a developing processing and a heat treatment required for the developing processing. Through these operations, the controller 100 completes the substrate processing for the single sheet of workpiece W.

### <Liquid Processing Device>

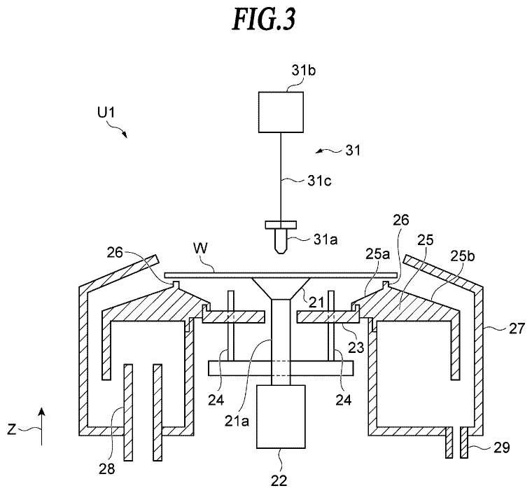

Now, an example of the liquid processing device U1 will be explained in detail. As depicted in FIG. 3, the liquid processing device U1 includes, by way of example, a holder 21, a rotational driver 22, a supporting pin 24, a guide ring 25, a cup 27, an exhaust pipe 28, and a drain port 29. Further, the liquid processing device U1 has a processing liquid supply 31. The liquid processing device U1 may sometimes be equipped with multiple kinds of processing liquid supplies 31. The following description will be provided for an example where only one kind of processing liquid supply 31 is provided.

The holder 21 is a spin chuck configured to hold the workpiece W horizontally. The holder 21 may hold a rear surface of the workpiece W by attraction. The holder 21 is connected to the rotational driver 22 via a shaft 21a extending in a vertical direction (up-and-down direction). The rotational driver 22 is configured to rotate the holder 21 at a predetermined rotation speed based on a control signal outputted from the controller 100.

An enclosure plate 23 is provided around the shaft 21a, and the supporting pin 24 is extended in the vertical direction to penetrate the enclosure plate 23. The supporting pin 24 is a pin capable of supporting the rear surface of the workpiece W, and, as an example, three supporting pins 24 are provided around the shaft 21a. The supporting pins 24 are configured to be movable up and down by an elevating mechanism (not shown). The workpiece W is transferred between a transfer mechanism (not shown) for the workpiece W and the holder 21 by the supporting pins 24.

The guide ring 25 is provided below the workpiece W held by the holder 21, and has a function of guiding the processing liquid supplied to the front surface of the workpiece W toward the drain port. At least a part of the guide ring 25 is located on the rear surface side of (vertically below) the workpiece W when the workpiece W is held by the holder 21. In a plan view (when viewed from above), at least a part of the guide ring 25 is covered with the workpiece W. The cup 27 is disposed around the guide ring 25 to surround it to thereby suppress scattering of the processing liquid. The top of the cup 27 is open so that the workpiece W can be transferred to the holder 21. A space serving as a liquid discharge path is formed between an inner peripheral surface of the cup 27 and an outer periphery of the guide ring 25. Further, an exhaust port and the drain port 29 for draining a liquid having passed through the space are provided under the cup 27.

The guide ring 25 is formed to widen from a periphery of the enclosure plate 23 toward the cup 27, and is a member (annular member) having a circular ring shape in a plan view. The guide ring 25 is located under the workpiece W held by the holder 21. A lower portion of the guide ring 25 is connected to an inner wall of the cup 27 so that the processing liquid is suppressed from leaking out of the cup 27.

A top surface of the guide ring 25 is composed of inclined surfaces 25a and 25b. The inclined surface 25a is located closer to the center of the cup 27 than the inclined surface 25b is. The inclined surface 25a is sloped upwards as it goes toward the outside of the cup 27, and the inclined surface 25b is sloped downwards as it goes towards the outside of the cup 27. As a result, the guide ring 25 has a longitudinal cross section of a mountain shape.

A ring top end 26 (annular protrusion) is formed at a boundary between the inclined surfaces 25a and 25b of the guide ring 25 as this gradient becomes steeper. The ring top end 26 is formed to protrude upwards along a circumferential direction of the workpiece W disposed on the above-described holder 21, and is positioned close to a periphery of the workpiece W. This ring top end 26 suppresses the processing liquid supplied to the front surface of the workpiece W from flowing to the rear surface of the workpiece W and adhering to a position near the center of the workpiece W, or suppresses mist of the processing liquid from adhering to a position near the center of the rear surface of the workpiece W. The relative position of the guide ring 25 with respect to the cup 27 may be changed. Thus, the relative height of the ring top end 26 with respect to the workpiece W and the holder 21 supporting the workpiece W may be changed.

The processing liquid supply 31 is configured to discharge the processing liquid from above the workpiece W held by the holder 21 toward the front surface of the workpiece W. The processing liquid supply 31 may discharge the processing liquid toward a peripheral region (a region including the periphery and the vicinity thereof) on the front surface of the workpiece W.

The processing liquid supply 31 includes a nozzle 31a, a processing liquid supply source 31b, and a pipeline 31c. The pipeline 31c may be provided with an opening/closing valve controlled by the controller 100. As an open state and a closed state of the opening/closing valve is switched in response to a control signal from the controller 100, a supply and a stop of the supply of the processing liquid may be switched.

The nozzle 31a is mounted on, for example, an arm extending in a horizontal direction, and is configured to be movable in a horizontal direction. The nozzle 31a is also configured to be movable in a vertical direction as well. The liquid processing device U1 is provided with a moving mechanism configured to move the nozzle 31a in the horizontal direction and the vertical direction. Through the operation of the moving mechanism, the nozzle 31a can be moved between a standby position outside the cup 27 and a position above the workpiece W.

The processing liquid supplied from the processing liquid supply 31 may include, for example, a processing liquid (for example, a resist liquid) for use in forming a coating film on the periphery of the workpiece W and a solvent. The processing liquid supplied from the processing liquid supply 31 may be a developing liquid. When it is necessary to supply a plurality of processing liquids to the workpiece W, a plurality of processing liquid supplies 31 may be provided in the liquid processing device U1.

When the controller 100 controls the liquid processing device U1 described above, the liquid processing device U1 performs the liquid processing on the workpiece W according to predetermined conditions. For example, the controller 100 supplies the processing liquid to the workpiece W through the processing liquid supply 31 based on the predetermined conditions, and also controls the rotation of the workpiece W at that time. The controller 100 may be composed of a plurality of functional modules configured to carry out the above-described liquid processing. Each functional module may not be limited to being implemented by execution of a program, but may be implemented by a dedicated electric circuit (for example, a logic circuit) or an ASIC (Application Specific Integrated Circuit) as an integration of these electric circuits.

### (Information Collection System)

The information collection system 7 shown in FIG. 1 is a system configured to acquire information regarding the substrate processing apparatus 2. The information collection system 7 is equipped with an inspection wafer 8 (inspection substrate) and an information collection device 9.

In the substrate processing apparatus 2 (coating and developing apparatus 2A), the inspection wafer 8 may be transferred by the various transfer devices belonging to the coating and developing apparatus 2A in the same manner as the workpiece W is transferred. The inspection wafer 8 may acquire image data by imaging a member located on the rear surface side of the workpiece W when the holder 21 is holding the workpiece W. Then, the inspection wafer 8 acquires, from the image data, information indicating a height position of the member located on the rear surface side of the workpiece W when the workpiece W is placed on the holder 21.

In the present disclosure, the member which is located on the rear surface side of the workpiece W when the holder 21 is holding the workpiece W and for which the information indicating the height position is acquired by the inspection wafer 8 is referred to as a “functional member.” The functional member is a member that has a preset function in a substrate processing apparatus. The guide ring 25 of the liquid processing device U1 is an example of the functional member having a function of suppressing the processing liquid from flowing to the rear surface of the workpiece W. Hereinafter, the information collection system 7 will be described for an example where the functional member is the guide ring 25.

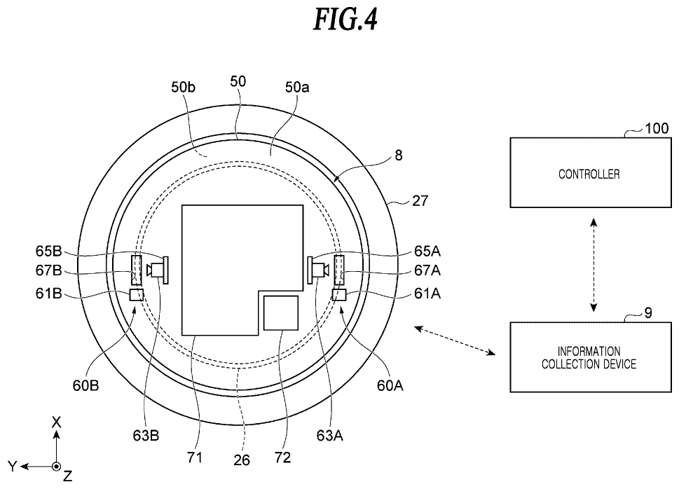

In a part of FIG. 4, the inspection wafer 8 is schematically illustrated. The inspection wafer 8 is configured to be transferred in the coating and developing apparatus 2A to perform, in the liquid processing device U1, an inspection of the liquid processing device U1. When the inspection wafer 8 performs the inspection of the liquid processing device U1, the workpiece W is not carried into the liquid processing device U1, and the liquid processing on the workpiece W is not performed. The inspection wafer 8 is configured to measure a height position of the ring top end 26 of the guide ring 25 in the vertical direction. The height position of the ring top end 26 is also a distance between the bottom surface of the workpiece W and the ring top end 26 when the workpiece W is held by the holder 21.

When assembling the liquid processing device U1 or adjusting it for maintenance, the height position of the ring top end 26 may deviate from an appropriate range. If a liquid processing is performed on the workpiece W in this state, the ring top end 26 may come into contact with the workpiece W, or the ring top end 26 may be distanced too far away from the workpiece W. In order to suppress such problems, the inspection wafer 8 is transferred to the liquid processing device U1 instead of the workpiece W, and images the ring top end 26 while being supported on the holder 21 like the workpiece W, thus acquiring image data of the ring top end 26. Then, the height position of the ring top end 26 is calculated from the image data obtained by imaging the ring top end 26 in this way.

The inspection wafer 8 includes, for example, a main body 50, a first measurer 60A, a second measurer 60B, a device mounting board 71, and a battery 72.

The main body 50 has a bottom surface 50b that can be held by the holder 21. The main body 50 may be a substrate of the same size as the workpiece W in a plan view, or may be of a circular shape. The bottom surface 50b of the main body 50 is also a rear or bottom surface of the main body 50. The first measurer 60A, the second measurer 60B, the device mounting board 71, and the battery 72 are provided on a top surface 50a of the main body 50. Like the workpiece W, the main body 50 is transferred to the holder 21 by the transfer devices within the coating and developing apparatus 2A and the supporting pins 24 of the liquid processing device U1. A central portion of the bottom surface 50b of the main body 50 may be attracted by the holder 21, and the bottom surface 50b of the main body 50 may be flat like the rear surface of the workpiece W. Further, FIG. 4 illustrates the inspection wafer 8 held by the holder 21.

The first measurer 60A is configured to measure a distance between the main body 50 and the ring top end 26 (guide ring 25) in the state that the main body 50 is held by the holder 21. The second measurer 60B is configured to measure the distance between the main body 50 and the ring top end 26 (guide ring 25) in the state that the main body 50 is held by the holder 21. The first measurer 60A is used to inspect, for example, the liquid processing device U1 (a device configured to perform a liquid processing for film formation) of the processing modules 11, 12, and 13. The second measurer 60B is used to inspect, for example, the liquid processing device U1 (a device configured to perform a developing processing) of the processing module 14.

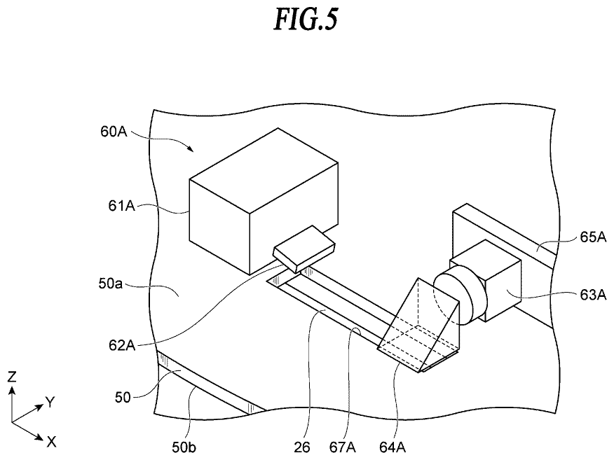

The first measurer 60A and the second measurer 60B are disposed at mutually different positions in a circumferential direction around the center of the main body 50. The first measurer 60A and the second measurer 60B have the same configuration. As depicted in FIG. 4 and FIG. 5, the first measurer 60A includes, by way of example, a light source 61A, a mirror member 62A, a camera 63A, a prism 64A, and a calculator 65A.

The light source 61A and the mirror member 62A are fixed to the main body 50 and function as a radiator configured to radiate a measurement wave to the guide ring 25 from diagonally above it. The light source 61A and the mirror member 62A are fixed to the top surface 50a of the main body 50, and radiate the measurement wave in an inclined direction with respect to the bottom surface 50b of the main body 50. The light source 61A and the mirror member 62A serve as the radiator configured to radiate light as the measurement wave. In FIG. 5, etc., illustration of a member for fixing the mirror member 62A is omitted.

The main body 50 is provided with, in a peripheral region thereof, a through hole 67A that is formed through the main body 50 in a plate thickness direction. With the main body 50 held by the holder 21 such that the center of the main body 50 is approximately coincident with a rotation center of the holder 21, at least a portion of an opening of the through hole 67A overlaps the ring top end 26, when viewed from vertically above. Thus, it is possible to radiate the light from the light source 61A and the mirror member 62A located above the main body 50 to the ring top end 26 through the through hole 67A.

The through hole 67A may be formed to extend along a tangential direction of a circle around the center of the main body 50. In the present disclosure, the direction in which the through hole 67A extends (a lengthwise direction of the opening of the through hole 67A) is referred to as an X axis. The radiator composed of the light source 61A and the mirror member 62A radiates the light to the ring top end 26 of the guide ring 25 such that the light propagates along the X-axis direction in a plan view.

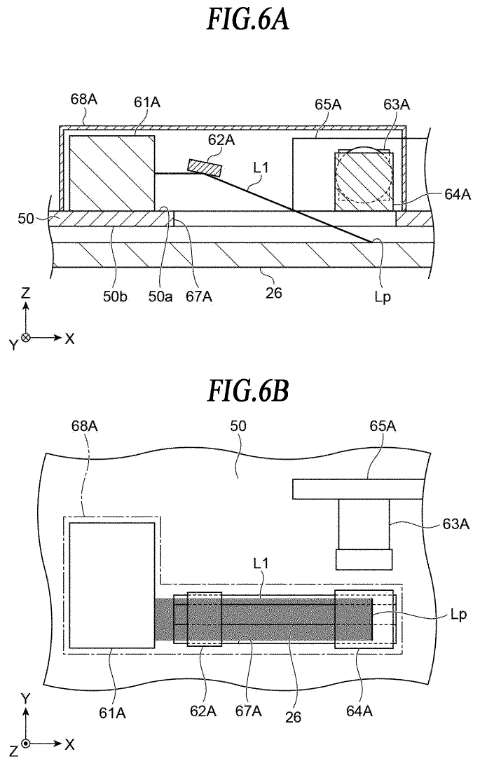

The light source 61A may emit band-shaped light. The band-shaped light can also be referred to as line light. The light source 61A emits line light L1 extending along the bottom surface 50b of the main body 50. The line light L1 may be laser light. The line light L1 emitted from the light source 61A is reflected by the mirror member 62A to be directed downwards (diagonally downwards). The line light L1 from the mirror member 62A passes through the through hole 67A and reaches a top surface of the ring top end 26 located below the main body 50 (see FIG. 6A).

The line light L1 extends along the bottom surface 50b of the main body 50 and, also, in a direction intersecting a direction in which the light from the radiator composed of the light source 61A and the mirror member 62A propagates. The direction in which the light from the radiator propagates is defined as, for example, a direction in which the light propagates after being emitted from the mirror member 62A. At a certain moment, the line light L1 is observed to extend in the Y-axis direction, for example. The line light L1 observed at a certain moment may extend along the bottom surface 50b of the main body 50 and may be orthogonal to the direction in which the light from the radiator travels.

As illustrated in FIG. 6B, the length of the line light L1 is set to a value larger than the width of the ring top end 26. The width of the ring top end 26 is a width in a radial direction of the circle around the center of the main body 50. By setting the length of the line light L1 to be larger than the width of the ring top end 26, the line light L1 can be radiated to (reach) the ring top end 26 even when the relative position between the ring top end 26 and the inspection wafer 8 slightly changes.

The camera 63A is fixed to the main body 50 and functions as a detector configured to detect a response resulting from the radiation of the measurement wave from the radiator. The camera 63A is configured to image the guide ring 25 irradiated with the light. The prism 64A is disposed on an optical axis of the camera 63A. The prism 64A is configured to image the ring top end 26 located below the main body 50 and the vicinity of the ring top end 26 through the through hole 67A. Therefore, the camera 63A is capable of imaging members below the main body 50 through the through hole 67A and the prism 64A.

When the inspection wafer 8 is held by the holder 21, the prism 64A is positioned vertically above the ring top end 26, and the camera 63A is capable of imaging, through the prism 64A, a part of the top surface of the ring top end 26 in the circumferential direction. As described above, the first measurer 60A is provided with an optical system composed of the mirror member 62A and the prism 64A. Even without providing this optical system, the light can be directly radiated from the light source 61A to the ring top end 26, and the top surface of the ring top end 26 can be directly imaged by the camera 63A. However, by providing the above-described optical system and making a part of the optical axis horizontal, the size of the inspection wafer 8 in the thickness direction can be reduced as compared to the case where the optical system is not provided.

As shown in FIG. 6A, the line light L1 reaches the top surface of the ring top end 26 via the mirror member 62A. At this time, as depicted in FIG. 6B, a bright line Lp with increased radiation intensity of the line light L1 may be formed at a position on the top surface of the ring top end 26 where the line light L1 has arrived. By specifying the position of the bright line Lp from the image obtained by the camera 63A, an irradiation position (arrival position) of the line light L1 on the ring top end 26 can be specified.

The calculator 65A is configured to acquire information on the distance between the main body 50 and the guide ring 25 based on the response detected by the detector described above. The distance between the main body 50 and the guide ring 25 is defined as a distance between the bottom surface 50b of the main body 50 and the top surface of the ring top end 26 of the guide ring 25 in the vertical direction. The calculator 65A specifies the irradiation position of the line light L1 on the ring top end 26 from the image taken by the camera 63A, for example. Then, the calculator 65A acquires information on the distance between the main body 50 and the ring top end 26 based on the information indicating the specified irradiation position.

The calculator 65A may acquire the information on the distance between the main body 50 and the ring top end 26 based on a model representing a relationship between the irradiation position of the line light L1 on the ring top end 26 and the distance between the main body 50 and the ring top end 26. A specific example of the method of acquiring the information on the distance between the main body 50 and the ring top end 26 will be described later.

The first measurer 60A may include a cover member 68A. The cover member 68A is a member that covers at least the through hole 67A. In a plan view, an outer edge of the cover member 68A surrounds the opening edge of the through hole 67A. The cover member 68A has a function of suppressing disturbance light other than the line light L1 from reaching the top surface of the ring top end 26 through the through hole 67A. The cover member 68A may cover the light source 61A, the mirror member 62A, the prism 64A, and the through hole 67A in the plan view. The cover member 68A surrounds (from the side) the whole structure including the light source 61A, the mirror member 62A, the prism 64A, and the through hole 67A, except for the portion where the optical axis from the prism 64A to the camera 63A is located. In FIG. 5, illustration of the cover member 68A is omitted.

Referring back to FIG. 4, the second measurer 60B includes, by way of example, a light source 61B, a mirror member, a camera 63B, a prism, and a calculator 65B. Illustration of the mirror member and the prism of the second measurer 60B is omitted. Each member belonging to the second measurer 60B has the same function as the corresponding member belonging to the first measurer 60A. The respective members of the second measurer 60B are disposed near the through hole 67B which is formed at the main body 50. The second measurer 60B may include a cover member that covers at least the through hole 67B.

Although the members corresponding between the first measurer 60A and the second measurer 60B have the same functions, their performance (specification) may be different. In the liquid processing device U1 configured to perform the developing processing, a larger amount of the processing liquid tends to be supplied to the front surface of the workpiece W, as compared to the liquid processing device U1 configured to perform the film formation. For this reason, in the inspection of the liquid processing device U1 configured to perform the developing processing, it may be required to measure the height position of the ring top end 26 with higher accuracy than in the liquid processing device U1 configured to perform the film formation. As an example, the number of pixels of the camera 63B of the second measurer 60B is larger than the number of pixels of the camera 63A of the first measurer 60A. The intensity of the light (laser light) from the light source 61B of the second measurer 60B may be larger than the intensity of the light (laser light) from the light source 61A of the first measurer 60A.

The device mounting board 71 is provided at a central portion of the main body 50, for example. The camera 63A, the calculator 65A, the camera 63B, and the calculator 65B may be connected to the device mounting board 71 via a non-illustrated cable. The image data acquired by each of the cameras 63A and 63B and the calculation results obtained by each of the calculators 65A and 65B may be transmitted to the device mounting board 71 via the cable.

The device mounting board 71 is composed of a plurality of boards including, for example, a digital signal processor (DSP) board. However, for the convenience of explanation, the device mounting board 71 is described as a single board. Various types of devices may be mounted on the device mounting board 71. These various devices include a device configured to switch on and off of the light radiation by each of the light source 61A and the light source 61B by wirelessly receiving a signal from the information collection device 9. In addition, the various devices include a device configured to perform imaging by each of the camera 63A and camera 63B, and a device (transmitter) configured to transmit the calculation results by each of the calculator 65A and calculator 65B to the information collection device 9.

The device mounting board 71 may be composed of a plurality of functional modules configured to perform the above-described processing in the inspection wafer 8. Each functional module is not limited to being implemented by execution of a program, but may be implemented by a dedicated electric circuit (for example, a logic circuit) or an ASIC as an integration of these electric circuits.

The battery 72 is provided at the central portion of the main body 50, for example. The battery 72 supplies powers to the light sources 61A and 61B, the cameras 63A and 63B, the calculators 65A and 65B, and the respective devices included in the device mounting board 71.

The inspection wafer 8 performs inspection operations based on an instruction from the information collection device 9, and transmits information indicating an inspection result to the information collection device 9. For example, based on the instruction from the information collection device 9, the inspection wafer 8 performs the acquisition of image data for estimating the distance between the bottom surface of the workpiece W (bottom surface of the inspection wafer 8) and the ring top end 26, and the calculation using the acquired image data. The inspection wafer 8 transmits information indicating the result of the calculation using the image data to the information collection device 9.

The information collection device 9 is a device configured to operate the inspection wafer 8 at an appropriate timing in connection with the controller 100. Information indicating a transfer state of the inspection wafer 8 in the coating and developing apparatus 2A is sent to the information collection device 9 from the controller 100. By way of example, information (notification) indicating that the inspection wafer 8 has been transferred to the liquid processing device U1 and placed on the holder 21 is sent to the information collection device 9 from the controller 100. The information collection device 9 controls the inspection wafer 8 based on the notification from the controller 100, and causes the inspection wafer 8 to perform the imaging and the calculation for the estimation of the distance between the bottom surface of the inspection wafer 8 and the ring top end 26. When the information collection device 9 collects the estimation result from the inspection wafer 8, it may determine whether the estimation result is within a predetermined appropriate range and decide whether to carry on the subsequent processing based on this determination result.

The information collection device 9 may be composed of a plurality of functional modules configured to output/input the information between the controller 100 and the inspection wafer 8 and configured to perform a processing such as the determination based on the inspection result of the inspection wafer 9 in the information collection device 9. Each functional module is not limited to being implemented by execution of a program, but may be implemented by a dedicated electric circuit (for example, a logic circuit) or an ASIC as an integration of these electric circuits.

### (Hardware Configurations of Controller, Inspection Wafer, and Information Collection Device)

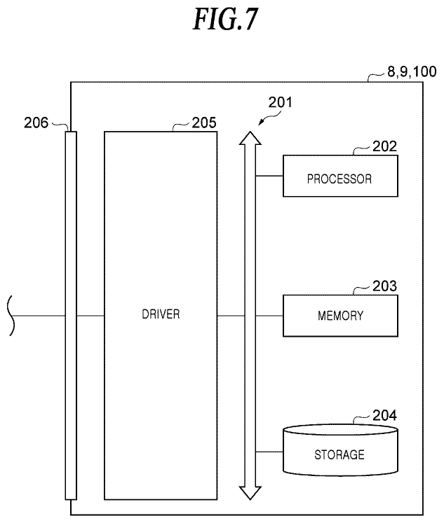

Hardware of each of the controller 100, the inspection wafer 8 (calculators 65A and 65B, and the device mounting board 71), and the information collection device 9 may be composed of one or more control computers. Each of the controller 100, the inspection wafer 8, and the information collection device 9 includes, as a hardware component, a circuit 201, as shown in FIG. 7. The circuit 201 may be composed of electric circuit elements (circuitry). The circuit 201 may include a processor 202, a memory 203, a storage 204, a driver 205, and an input/output port 206.

The processor 202 constitutes the aforementioned individual functional modules by executing the program in cooperation with at least one of the memory 203 and the storage 204 and performing an input/output of signals through the input/output port 206. The memory 203 and the storage 204 stores the various types of information and the program used in each of the controller 100, the inspection wafer 8, and the information collection device 9. The driver 205 is a circuit configured to drive functional components related to each of the controller 100, the inspection wafer 8, and the information collection device 9. The input/output port 206 performs an input/output of signals between the driver 205 and the related functional components.

The substrate processing system 1 may be equipped with one controller 100, or a controller group (control module) composed of a multiple number of controllers 100. When the substrate processing system 1 is equipped with the controller group, each of the aforementioned functional modules may be implemented by a single discrete controller or a combination of two or more controllers 100. If the controller 100 is composed of a plurality of computers (circuits 201), each of the aforementioned functional modules may be implemented by a single computer (circuit 201).

The controller 100 may be implemented by a combination of two or more computers (circuits 201). The controller 100 may include a plurality of processors 202. In this case, each of the aforementioned functional modules may be implemented by a single processor 202 or a combination of two or more processors 202. Some of the functions of the controller 100 of the substrate processing system 1 may be provided in a device separate from the substrate processing system 1, and this separate device may be connected to the substrate processing system 1 via a network to implement the various operations of the present exemplary embodiment. By way of example, if the functions of processors 202, memories 203, and storages 204 of a plurality of substrate processing systems 1 are combined and implemented as one or more separate devices, it may become possible to collectively manage and control information and operations of the plurality of substrate processing systems 1 remotely.

### <Measurement of Height by Measurer>

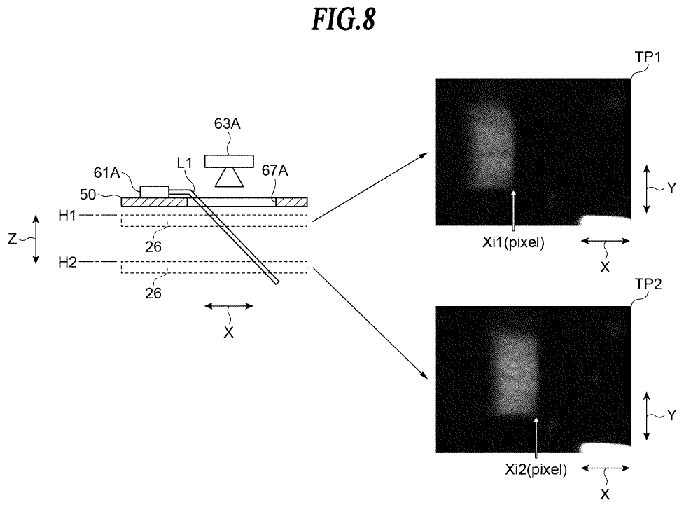

FIG. 8 shows a relationship between a distance between the main body 50 and the ring top end 26 and an image taken by the camera 63A. A taken image TP1 obtained when the top surface of the ring top end 26 is located at a height H1 and a taken image TP2 obtained when the top surface of the ring top end 26 is positioned at a height H2 are shown. The height H1 is a height position closer to the main body 50 as compared to the height H2. That is, when the top surface of the ring top end 26 is located at the height H1, the distance between the main body 50 and the ring top end 26 is small, whereas when the top surface of the ring top end 26 is located at the height H2, the distance between the main body 50 and the ring top end 26 is large.

The taken image TP1 and the taken image TP2 are collectively referred to as “taken image TP.” In the taken image TP, a horizontal direction on the image corresponds to the X-axis direction, and a vertical direction on the image corresponds to the Y-axis direction. In the taken image TP, a region that glows bright is a location on the top surface of the ring top end 26 irradiated with the line light L1. For example, the calculator 65A specifies an X-coordinate of an edge portion in the region glowing bright in the taken image TP as the irradiation position of the line light L1 on the ring top end 26. The edge portion is a boundary between the portion irradiated with the light and a portion which is not irradiated with the light. The calculator 65A may calculate the X-coordinate of the edge portion based on a difference in brightness (a difference in pixel values) between neighboring pixels.

As can be seen from a schematic diagram on the left side of FIG. 8, the irradiation position of the line light L1 on the ring top end 26 differs depending on the distance between the main body 50 and the ring top end 26. That is, the irradiation position of the line light L1 specified in the taken image TP differs depending on the distance between the main body 50 and the ring top end 26. For this reason, a model M configured to estimate the distance may be constructed before the distance is acquired in the inspection using the inspection wafer 8, and the distance may be estimated based on the model M and the irradiation position of the line light L1 specified in the taken image TP.

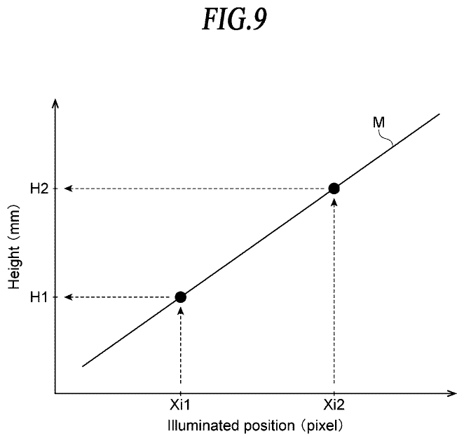

FIG. 9 presents a graph showing an example of the model M. The model M shows a relationship between the irradiation position of the line light L1 specified in the taken image TP and the distance between the main body 50 and the ring top end 26. In the graph shown in FIG. 9, a horizontal axis represents the irradiation position (illuminated position) of the line light L1 specified in the taken image TP, and a vertical axis represents the distance between the main body 50 and the ring top end 26 (i.e., the height position of the top surface of the ring top end 26).

When preparing the model M, the distance between the main body 50 and the ring top end 26 is measured by a measuring cage. The model M may be constructed from a plurality of data sets each including the irradiation position of the line light L1 in the taken image TP and the measurement value of the distance when the irradiation position is obtained. If the irradiation position of the line light L1 is defined as x and the distance between the main body 50 and the ring top end 26 is defined as y, the model M is expressed by an approximation function of y=f(x). The model M may be a first-order approximation function or a second-order or higher approximation function.

After the model M is prepared, when performing the inspection of the liquid processing device U1 in which the distance between the main body 50 and the ring top end 26 is unknown, the calculator 65A specifies the irradiation position of the line light L1 on the ring top end 26 in the taken image TP. For example, the calculator 65A specifies (calculates) a coordinate with the largest difference in brightness on the image in the X-axis direction as a representative point indicating the irradiation position of the line light L1.

The X-coordinate with the largest difference in brightness on the image may change depending on the Y-coordinate (position in the Y-axis direction). For this reason, the calculator 65A may acquire the representative point in the X-axis direction by calculating a statistical value such as an average value, a mode, or a median value after calculating the X-coordinate with the largest difference in brightness for each Y-coordinate. In this case, the input of the model M may be the representative point in the X-axis direction.

In the taken image TP1 shown in FIG. 8, a representative point Xi1 in the X-axis direction is acquired. In the taken image TP2, a representative point Xi2 in the X-axis direction is acquired. The representative points Xi1 and Xi2 are expressed as pixel values (coordinates). The calculator 65A inputs the representative point Xii or the representative point Xi2 into the model M, and acquires a value outputted from the model M as a distance according to the representative point. When the second measurer 60B is used, the distance between the main body 50 and the ring top end 26 may be obtained in the same way as in the case where the first measurer 60A is used.

### Information Collection Method

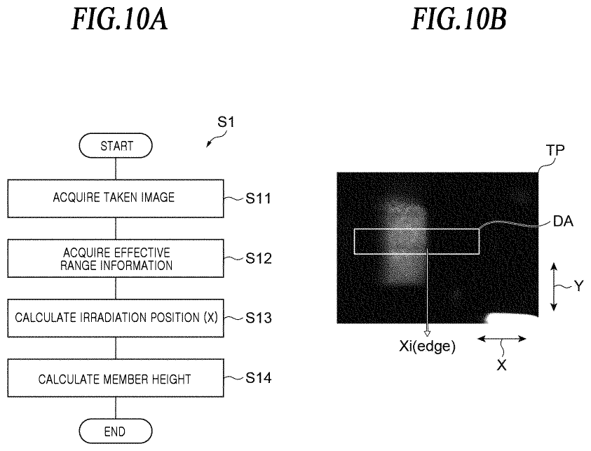

Now, referring to FIG. 10A and FIG. 10B, an example of an information collection method performed in the information collection system 7 will be described. As an example of the information collection method, a method in which the distance between the main body 50 and the ring top end 26 is calculated from the image data by the first measurer 60A will be explained. A processing flow S1 shown in FIG. 10A is executed in the state that the inspection wafer 8 is held by the holder 21 of the liquid processing device U1.

In the processing flow S1, the inspection wafer 8 first performs a process S11. For example, in the process S11, with the line light L1 emitted from the light source 61A, the calculator 65A acquires the taken image TP by causing the camera 63A to take it. FIG. 10B illustrates an example of the taken image TP.

Then, the inspection wafer 8 performs a process S12. For example, in the process S12, the calculator 65A acquires, in the taken image TP, information indicating an effective range DA in which a processing of specifying the irradiation position of the line light L1 on the ring top end 26 is to be performed. The information indicating the effective range DA is set in advance by an operator, for example. Various types of guide rings 25 may be used in the liquid processing device U1, and the information indicating the effective range DA may be set for each type of the guide rings 25.

The effective range DA means that the irradiation position of the line light L1 is specified within that range. When calculating the position of the edge portion in the X-axis direction as stated above to specify the irradiation position of the line light L1, there may exist a range in which the position of the edge portion varies greatly depending on the position in the Y-axis direction. The effective range DA is set to exclude this range in which the variation in the position of the edge portion is large. Additionally, the effective range DA is set so as not to include a range with a large variation in the representative point even if the relative position of the inspection wafer 8 with respect to the holder 21 changes slightly. Furthermore, when the inspection wafer 8 is used for the inspection of various functional members, it is difficult to limit the field of view of the camera 63A to the effective range DA.

Next, the inspection wafer 8 performs a process S13. For example, in the process S13, the calculator 65A calculates, within the effective range DA, the representative point Xi in the X-axis direction without considering information of regions other than the effective range DA in the taken image TP. In one example, the calculator 65A may calculate the X-coordinate with a large difference in brightness while observing it from the right end on the image for each Y-coordinate, and then calculate a statistical value such as an average value of the calculation results of the X-coordinate as the representative point Xi. As described above, the calculator 65A may specify the irradiation position of the line light L1 on the ring top end 26 within the effective range DA, which is a preset part of taken image TP.

Thereafter, the inspection wafer 8 performs a process S14. For example, in the process S14, the calculator 65A determines the distance between the main body 50 and the ring top end 26 (height of the top surface of the ring top end 26) based on the representative point Xi obtained in the process S13 and the model M. The calculator 65A may output information indicating the calculation result of the distance to the device mounting board 71, and the device mounting board 71 may output the received information indicating the calculation result of the distance to the information collection device 9.

Through the process S14, the calculation of the above-described distance in the single liquid processing device U1 is completed. The inspection wafer 8 may execute the processing flow S1 in each of the other one or more liquid processing devices U1 as well. This processing flow S1 may also be executed when the second measurer 60B is used.

### Modification Examples

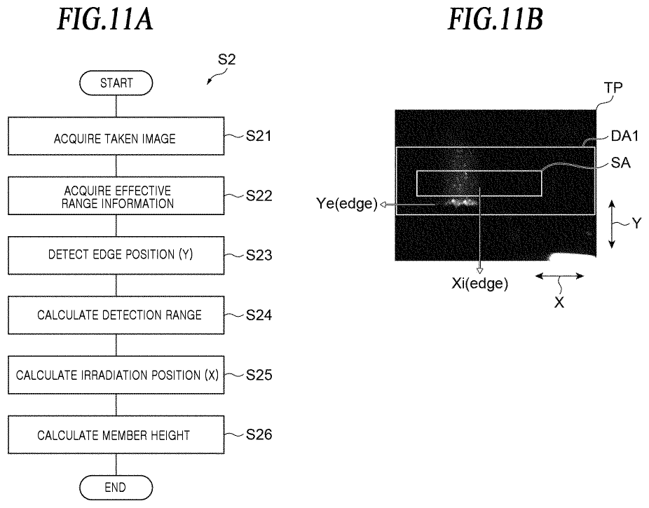

Instead of the processing flow S1, a processing flow S2 shown in FIG. 11A may be executed. In the processing flow S2, a method of setting a range in which a representative point is detected is different from that of the processing flow S1. In the processing flow S2, the inspection wafer 8 first performs a process S21, which is the same as the process S11 in the processing flow S1.

Next, the inspection wafer 8 performs a process S22. For example, in the process S22, the calculator 65A acquires, in the taken image TP, information indicating an effective range DA1 in which a processing in the subsequent process S23 is to be performed. The effective range DA1 is set in advance by the operator, for example.

Depending on the type of the guide ring 25, the line light L1 is strongly reflected at a periphery (edge) of the top surface of the ring top end 26 in its width direction by being affected by a bur or the like. In this case, as can be seen from the taken image TP shown in FIG. 11B, a portion corresponding to the edge of the ring top end 26 is brighter than the other regions. If a representative point in the X-axis direction is detected by including such bright spot in the detection range, there is a risk that an error in the detection result of the representative point may increase. The effective range DA1 is set to include the portion corresponding to the edge of the ring top end 26.

Subsequently, the inspection wafer 8 performs a process S23. For example, in the process S23, the calculator 65A specifies, within the effective range DA1, the Y-coordinate of the portion brightened due to the edge of the ring top end 26. For example, the calculator 65A calculates, for each X-coordinate, the Y-coordinate where the difference in brightness is largest between neighboring pixels adjacent to each other in the Y-axis direction. Then, the calculator 65A specifies a statistical value such as an average value of the calculation results of the Y-coordinate for each X-coordinate as an edge position Ye representing the boundary between the portion irradiated with light and the portion which is not irradiated with light.

Then, the inspection wafer 8 performs a process S24. For example, in the process S24, the calculator 65A calculates, in the taken image TP, a detection range SA that is apart from the edge position Ye specified in the process S23 by a predetermined amount. The detection range SA in the processing flow S2 corresponds to the effective range DA in the processing flow S1. In the Y-axis direction on the image, a distance of a present number of pixels exists between the detection range SA and the edge position Ye. In this case, the edge position Ye and the region nearby are not included in the detection range SA.

As described above, the calculator 65A may specify, from the taken image TP, the position (edge position Ye) of the boundary between the portion irradiated with light and the portion not irradiated with light in the Y-axis direction (second direction), which is along the bottom surface 50b of the main body 50 and is perpendicular to the direction (first direction) in which the light from the radiator propagates. Then, the calculator 65A may specify, in the taken image TP, the irradiation position of the line light L1 on the ring top end 26 within the detection range SA which is a partial range apart from the edge position Ye specified in the Y-axis direction by the predetermined amount.

Next, the inspection wafer 8 performs processes S25 and S26. For example, in the process S25, the calculator 65A performs the same process as the process S13 of the processing flow S1 within the detection range SA. In the process S26, based on the representative point Xi obtained in the process S25, the calculator 65A calculates the distance between the main body 50 and the ring top end 26 (the height of the top surface of the ring top end 26), in the same way as in the process S14 of the processing flow S1.

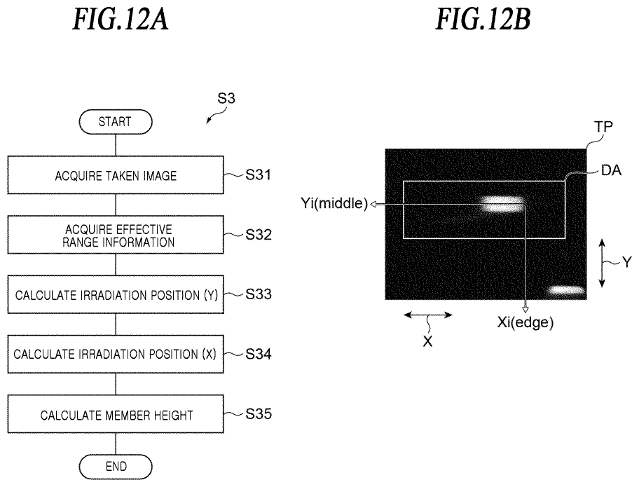

Instead of the processing flow S1, a processing flow S3 shown in FIG. 12A may be executed. In the processing flow S3, the aforementioned distance is acquired by specifying the irradiation position of the line light L1 on the ring top end 26 in each of the X-axis direction and the Y-axis direction, which is different from the processing flow S1. In the processing flow S3, the inspection wafer 8 performs processes S31 and S32 in the same way as in the processes S11 and S12 of the processing flow S1.

Due to distortion of a lens included in the camera 63A, some error may occur in a specific result of the irradiation position in the X-axis direction depending on the position in the Y-axis direction in the taken image TP. In other words, even if the top surface of the ring top end 26 is located at the same height position, the coordinate at which the representative point Xi in the X-axis direction is specified differs depending on the position in the Y-axis direction. For this reason, in order to calculate the distance between the main body 50 and the ring top end 26 with higher precision, it is necessary to perform the calculation by taking the irradiation position of the line light L1 in the Y-axis direction in the image into account as well.

Upon the completion of the process S32, the inspection wafer 8 performs processes S33 and S34. For example, in the process S33, the calculator 65A calculates the irradiation position of the line light L1 in the Y-axis direction within the taken image TP. The calculator 65A may calculate an intermediate position between an upper edge portion and a lower edge portion in the Y-axis direction as a representative point Yi indicating the irradiation position in the Y-axis direction. In the process S34, for example, the calculator 65A performs the same process as the process S13 of the processing flow S1 to calculate the representative point Xi.

Next, the inspection wafer 8 performs a process S35. For example, in the process S35, the calculator 65A calculates the distance between the main body 50 and the ring top end 26 (the height of the top surface of the ring top end 26) based on the representative points Xi and Yi obtained in the processes S33 and S34. As an example, the calculator 65A may calculate the distance by acquiring an output value from the model M representing the relationship between the representative point Xi and the distance and then correcting the output value with the representative point Yi. Instead of this correction, the calculator 65A may calculate the distance by using a model M representing a relationship between the representative points Xi and Yi and the distance.

As described above, the calculator 65A may specify, from the taken image TP, the irradiation position of the line light L1 on the ring top end 26 both in the direction (X-axis direction: first direction) in which the line light L1 from the radiator propagates and the Y-axis direction (second direction), which is along the bottom surface 50b of the main body 50 and is perpendicular to the direction in which the line light L1 from the radiator propagates in a plan view. Then, the calculator 65A may acquire information on the distance between the main body 50 and the ring top end 26 based on the information indicating the irradiation position of the line light L1 specified in each of the X-axis direction and the Y-axis direction.

The inspection wafer 8 may be capable of executing two or more of the processing flows S1, S2, and S3. The inspection wafer 8 may execute a processing flow specified by an instruction from the information collection device 9. The information collection device 9 may instruct the inspection wafer 8 which processing flow to execute depending on the type of the guide ring 25 to be measured. As an example, in the inspection of the liquid processing device U1 that performs the liquid processing for film formation, at least one of the processing flow S1 and the processing flow S2 is executed, and in the inspection of the liquid processing device U1 that performs the developing processing, the processing flow S3 is executed. In this way, by changing the processing flow for the inspection depending on the type of the liquid processing device U1 (depending on the content of the liquid processing performed by the liquid processing device U1), a processing load on the controller 100 may be reduced.

According to the instruction for the processing flow to be executed, the information collection device 9 may instruct the inspection wafer 8 which measurer to use and how to set a measurement parameter during the measurement. The measurement parameter includes, for example, the illuminance (intensity) of the line light L1 from the light source, the effective ranges DA and DA1, and the type of the model M used for calculation.

Each of the processing flows S1, S2, and S3 is an example and can be modified appropriately. In any one of the processing flow S1, the processing flow S2, and the processing flow S3, the inspection wafer 8 may perform one process and the next process in parallel, or may perform the individual processes in a different order from that stated above. The inspection wafer 8 may omit any one process in any one of the processing flow S1, the processing flow S2, and the processing flow S3, or may perform different processing from that stated above in any one process.

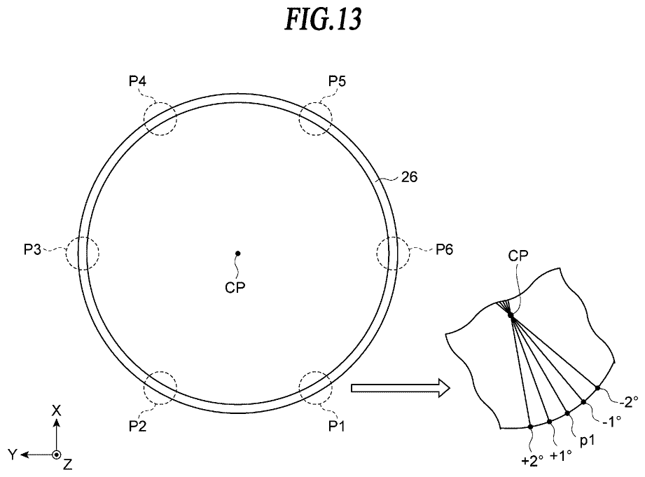

In detecting (inspecting) the height position at one location on the ring top end 26, information from a plurality of measurement points may be used. Specifically, the calculator 65A may acquire the information on the distance between the main body 50 and the ring top end 26 based on the responses (responses detected by the detector) at the plurality of measurement points located at different positions in the circumferential direction. Referring to FIG. 13, an example of calculating the distance from the responses at the plurality of measurement points will be described.

As an example, measurement locations P1 to P6 whose positions are mutually different from each other in the circumferential direction are set on the ring top end 26. The inspection wafer 8 acquires the distance between the main body 50 and the ring top end 26 at each of these measurement locations P1 to P6. The position of each measurement location can be expressed by an angle around a center CP of the ring top end 26. The measurement locations P1 to P6 may be equi-spaced from each other in the circumferential direction around the center CP.

It is assumed that the aforementioned distance is measured at the measurement location P1 by using the first measurer 60A. The inspection wafer 8 performs acquisition of the taken image TP with the camera 63A at each of the plurality of measurement points in the measurement location P1. The plurality of measurement points include, for example, an angle p1 indicating the position of the measurement location P1, and two or more angles set on both sides of that angle p1 to be different from the angle P1 by a predetermined angle. In the example shown in FIG. 13, the plurality of measurement points are set at angles of p1 (°), (p1+1°), (p1+2°), (p1−1°), and (p1−2°).

The calculator 65A may calculate the representative point Xi from the taken image TP at each of the plurality of measurement points of the measurement location P1 to calculate the distance between the main body 50 and the ring top end 26. In addition, the calculator 65A may calculate a statistical value of the calculation results of the distance at the plurality of measurement points as a distance at the measurement location P1. The statistical value of the calculation results of the distance is, for example, an average value or a median value.

The calculator 65A may calculate the representative point Xi from the taken image TP at each of the plurality of measurement points of the measurement location P1. Further, the calculator 65A may calculate a statistical value (for example, an average value or a median value) of the calculation results of the representative point Xi at the plurality of measurement points as a representative point X1 at the measurement location P1. Thereafter, the calculator 65A may calculate the distance between the main body 50 and the ring top end 26 from the representative point Xi at the measurement location P1 by using the model M.

The inspection wafer 8 may measure the distance at each of the rest measurement locations P2 to P6 in the same manner as in the measurement at the measurement location P1. If a foreign matter is attached to any one measurement point of the ring top end 26, the calculation result of the distance may be largely deviated from the actual value due to the influence of that foreign matter. By conducting the calculation based on the plurality of taken images TP at the plurality of measurement points, it is possible to reduce the possibility that the calculation result of the distance may be largely deviated from the actual value due to the influence of the foreign matter or the like.

In the above-described examples, the functional member that is a target to be measured by the inspection wafer 8 is the guide ring 25 including the ring top end 26. However, the functional member may be an annular member other than the guide ring 25. Also, the functional member is not limited to the annular member, and it can be any member as long as it is located on the rear surface side of the workpiece W when the workpiece W is held by the holder 21 and has a defined function. The functional member may be any structure of the substrate processing apparatus, and is not limited to the member disposed in the liquid processing device U1. Other examples of the functional member may be an edge of a stage in a device configured to perform a gas treatment, a cleaning nozzle in a device configured to clean a peripheral region of a front surface of the workpiece W, and a rear nozzle disposed on the rear surface side of the workpiece W.

In the above-described examples, the calculator 65A of the first measurer 60A acquires the information on the distance between the main body 50 and the ring top end 26. However, the first measurer 60A may not have the calculator 65A. Instead, the device mounting board 71 may have the calculator 65A, and the distance may be calculated from the taken image TP obtained by the camera 63A. The inspection wafer 8 does not need to have the calculator 65A. Instead, the information collection device 9 may have the calculator 65A and calculate the distance from the taken image TP.

The inspection wafer 8 may not have either the first measurer 60A or the second measurer 60B, or may include one or more measurers in addition to the first measurer 60A and the second measurer 60B. The measurement wave radiated to the functional member is not limited to light, and may be a sound wave including an ultrasonic wave or the like. In this way, the type of the measurement wave is not limited. Besides, an appropriate device may be selected as the detector depending on the type of the measurement wave. In any one of the various examples described above, at least some of the matters described in the other examples may be combined.

### Summary of Present Disclosure

The present disclosure includes a configuration and a method of [1] to [16] below.

[1] An information collection system 1 (7) configured to acquire information on a substrate processing apparatus 2 (2A) having a holder 21 configured to hold a substrate W and a functional member 25 located on a rear surface side of the substrate W when the substrate W is held by the holder 21, the information collection system 1 (7) including:
a main body 50 having a bottom surface 50b allowed to be held by the holder 21;
a radiator 61A (62A) fixed to the main body 50, and configured to radiate a measurement wave L1 to the functional member 25 from obliquely above;
a detector 63A fixed to the main body 50, and configured to detect a response TP resulting from a radiation of the measurement wave L1 from the radiator 61A (62A); and
a calculator 65A configured to acquire information on a distance between the main body 50 and the functional member 25 based on the response TP detected by the detector 63A.

In the information collection system 1 (7), the measurement wave L1 is radiated to the functional member 25 from obliquely above. The response TP resulting from the radiation of the measurement wave L1 includes the information on the distance between the main body 50 and the functional member 25. Since the main body 50 has the bottom surface 50b, it is held by the holder 21 holding the substrate W. For this reason, the distance between the main body 50 and the functional member 25 is approximately equal to the distance between the substrate W held by the holder 21 and the functional member 25. Thus, with the above configuration, it is possible to obtain information on the distance between the functional member and the substrate in the substrate processing apparatus.

[2] The information collection system 1 (7) described in [1],
wherein the radiator 61A (62A) radiates light L1 as the measurement wave L1, and
the detector 63A is a camera configured to image the functional member 25 irradiated with the light L1.

By obtaining the information on the distance using various information included in the image captured by the camera, it is possible to obtain the information on the distance between the functional member and the substrate in the substrate processing apparatus with greater precision.

[3] The information collection system 1 (7) described in [2],
wherein the light L1 radiated from the radiator 61A (62A) is band-shaped light L1,
the band-shaped light L1 extends along the bottom surface 50b in a direction (Y-axis direction) intersecting a direction in which the light L1 from the radiator 61A (62A) propagates, and
the calculator 65A specifies, from an image taken by the camera 63A, an irradiation position of the band-shaped light L1 on the functional member 25, and acquires the information on the distance between the main body 50 and the functional member 25 based on information indicating the specified irradiation position.

By using the band-shaped light L1, even if a relative position between the functional member 25 and the main body 50 is changed slightly, it is possible to radiate the light to the functional member 25. Further, by using the band-shaped light L1, it is easy to specify the irradiation position of the light on the functional member 25 on the taken image by the camera 63A. Thus, it is possible to obtain the information on the distance between the functional member and the substrate in the substrate processing apparatus with greater precision.

[4] The information collection system 1 (7) described in [3],
wherein the calculator 65A acquires the information on the distance between the main body 50 and the functional member 25 based on a model M representing a relationship between the irradiation position of the band-shaped light L1 on the functional member 25 and the distance between the main body 50 and the functional member 25.

In this case, by using the model M, it is possible to obtain the information on the distance between the functional member and the substrate in the substrate processing apparatus with greater precision.

[5] The information collection system 1 (7) described in [3] or [4],
wherein the calculator 65A specifies the irradiation position of the band-shaped light L1 on the functional member 25 within a preset partial range DA of the image TP.

As described above, in order to specify the irradiation position of the light L1, a coordinate in one direction of a specific portion (for example, edge portion) of a region irradiated with the band-shaped light L1 is calculated in the image TP. In a certain range within the image TP, the coordinate in one direction of the specific portion may be greatly changed depending on a position in a direction orthogonal to the one direction. For this reason, by setting the partial range DA to exclude the range in which the coordinate is greatly changed, it is possible to specify the irradiation position of the light L1 with higher precision.

[6] The information collection system 1 (7) described in [3] or [4],
wherein the calculator 65A specifies, from the image TP, a position of a boundary Ye between a portion irradiated with the light L1 and a portion not irradiated with the light L1 in a second direction (Y-axis direction), which is along the bottom surface 50b and is perpendicular to a first direction in which the light L1 from the radiator 61A (62A) propagates, and specifies the irradiation position of the band-shaped light L1 on the functional member 25 within a partial range SA of the image TP which is apart from the boundary Ye specified in the second direction (Y-axis direction) by a preset amount.

As described above, depending on the type of the functional member 25, the light is strongly reflected at a periphery of the functional member in the second direction. As a result, the accuracy when specifying the irradiation position of the light L1 may be reduced. In the above configuration, the irradiation position of the light L1 is specified in the partial range SA which is apart from the boundary Ye corresponding to the periphery of the functional member in the second direction, so that the irradiation position of the light L1 can be specified more accurately.

[7] The information collection system 1 (7) described in [3] or [4],
wherein the calculator 65A specifies, from the image TP, the irradiation position of the band-shaped light L1 on the functional member 25 both in a first direction (X-axis direction) in which the light L1 from the radiator 61A (62A) propagates and a second direction (Y-axis direction) which is along the bottom surface 50b and is perpendicular to the direction in which the light L1 from the radiator 61A (62A) propagates in a plan view, and acquires the information on the distance between the main body 50 and the functional member 25 based on information Xi (Yi) indicating the irradiation position specified in each of the first direction (X-axis direction) and the second direction (Y-axis direction).

The irradiation position of the light L1 in the functional member 25 is varied in the first direction (X-axis direction) depending on the position of the functional member 25 with respect to the main body 50. As described above, the irradiation position of the light specified in the X-axis direction may be varied depending on the position in the second direction (Y-axis direction) by being affected by the lens of the camera 63A. In the above configuration, the information on the distance is obtained based on the irradiation position in the second direction (Y-axis direction), the information on the distance between the substrate and the functional member in the substrate processing apparatus can be obtained with higher accuracy.

[8] The information collection system 1 (7) described in any one of [1] to [7],
wherein the functional member 25 is formed in an annular shape,
the functional member 25 is provided with a protrusion 26 serving to suppress a processing liquid supplied to the substrate W from reaching a rear surface of the substrate, and
the distance between the main body 50 and the functional member 25 is a distance between the main body 50 and the protrusion 26.

The protrusion 26 of the functional member 25 is disposed near the substrate W from a viewpoint of suppressing an inflow of the processing liquid toward the rear surface. For this reason, it is required to determine the distance between the protrusion 26 and the substrate W. With the above configuration, the information on the distance between the protrusion 26 and the substrate W can be obtained, so that the distance between the protrusion 26 and the substrate W can be determined.

[9] The information collection system 1 (7) described in any one of [1] to [8],
wherein the functional member 25 is formed in an annular shape, and
the calculator 65A acquires the distance between the main body 50 and the functional member 25 based on the response TP at each of multiple measurement points located at mutually different positions in a circumferential direction.

If a foreign matter is attached to anyone measurement point in the annular-shaped functional member 25, acquisition result of the distance is largely deviated from an actual value due to the influence of the foreign matter. Based on the multiple responses TP at the multiple measurement points, it is possible to reduce the possibility that the acquisition result of the distance may be largely deviated from the actual value due to the influence of the foreign matter or the like.

[10] The information collection system described in any one of [1] to [9],
wherein the main body 50 is provided with a through hole 67A,
the radiator 61A (62A) radiates the measurement wave L1 to the functional member 25 through the through hole 67A, and the detector 63A detects the response TP through the through hole, and
wherein the information collection system 1 (7) further includes a cover member 68A configured to cover at least the through hole 67A.

In this case, disturbance light radiated to the functional member 25 through the through hole 67A can be covered by the cover member 68A. Thus, the information on the distance between the substrate and the functional member in the substrate processing apparatus can be obtained with higher accuracy.

[11] An inspection substrate 8 configured to acquire information on a substrate processing apparatus 2 (2A) including a holder 21 configured to hold a substrate W and a functional member 25 located on a rear surface side of the substrate W when the substrate W is held by the holder 21, the inspection substrate 8 including:
a main body 50 having a bottom surface 50b allowed to be held by the holder 21;
a radiator 61A (62A) fixed to the main body 50, and configured to radiate a measurement wave L1 to the functional member 25 from obliquely above; and
a detector 63A fixed to the main body 50, and configured to detect a response TP resulting from a radiation of the measurement wave L1 from the radiator 61A (62A).

By using the inspection substrate 8, the information on the distance between the functional member 25 and the main body 50 can be obtained from the response TP detected by the detector 63A. Thus, it is possible to obtain the information on the distance between the substrate and the functional member in the substrate processing apparatus.

[12] The inspection substrate 8 described in [11], further including:
a calculator 65A configured to acquire information on a distance between the main body 50 and the functional member 25 based on the response TP detected by the detector 63A.

In this case, since the information on the distance is obtained (calculated) from the inspection substrate 8 itself, information output to an outside from the inspection substrate 8 can be reduced.

[13] An information collection method of acquiring information on a substrate processing apparatus 2 (2A) having a holder 21 configured to hold a substrate W and a functional member 25 located on a rear surface side of the substrate W when the substrate W is held by the holder 21, the information collection method including:
holding a bottom surface 50b of a main body 50 with the holder 21;
radiating a measurement wave L1 from a radiator 61A (62A) fixed to the main body 50 to the functional member 25 from obliquely above;
detecting a response TP resulting from a radiation of the measurement wave L1 from the radiator 61A (62A) by a detector 63A fixed to the main body 50; and
acquiring information on a distance between the main body 50 and the functional member 25 based on the response TP detected by the detector 63A.

In the information collection method, it is possible to obtain the information on the distance between the substrate and the functional member in the substrate processing apparatus, the same as in the information collection system 1 (7) described in [1].

[14] The information collection method described in [13],
wherein in the radiating, the radiator 61A (62A) radiates light as the measurement wave L1, and
the detector 63A is a camera configured to image the functional member 25 irradiated with the light L1.

In this method, it is possible to obtain the information on the distance between the substrate and the functional member in the substrate processing apparatus with higher precision, the same as in the information collection system 1 (7) described in [2].

[15] The information collection method described in [14],
wherein in the radiating, the light L1 radiated from the radiator 61A (62A) is band-shaped light L1,
the band-shaped light L1 extends along the bottom surface 50b in a direction (Y-axis direction) intersecting a direction in which the light L1 from the radiator 61A (62A) propagates, and
in the acquiring, an irradiation position of the band-shaped light L1 on the functional member 25 is specified from an image TP taken by the camera 63A, and the information on the distance between the main body 50 and the functional member 25 is acquired based on information indicating the specified irradiation position.

In this method, it is possible to obtain the information on the distance between the substrate and the functional member in the substrate processing apparatus with higher precision, the same as in the information collection system 1 (7) described in [3].

[16] The information collection method described in any one of [13] to [15],
wherein the functional member 25 is formed in an annular shape,
the functional member 25 is provided with a protrusion 26 serving to suppress a processing liquid supplied to the substrate W from reaching a rear surface of the substrate W, and
in the acquiring, a distance between the main body 50 and the protrusion 26 is acquired as the information on the distance between the main body 50 and the functional member 25.

In this method, it is possible to determine the distance between the substrate W and the protrusion 26, the same as in the information collection system 1 (7) described in [8].

According to the exemplary embodiment, it is possible to provide the technique enabling acquisition of the information on the distance between the substrate and the functional member in the substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. An information collection system configured to acquire information on a substrate processing apparatus having a holder configured to hold a substrate and a functional member located on a rear surface side of the substrate when the substrate is held by the holder, the information collection system comprising:
a main body having a bottom surface allowed to be held by the holder;
a radiator fixed to the main body, and configured to radiate a measurement wave to the functional member from obliquely above;
a detector fixed to the main body, and configured to detect a response resulting from a radiation of the measurement wave from the radiator; and
a calculator configured to acquire information on a distance between the main body and the functional member based on the response detected by the detector.

2. The information collection system of claim 1,
wherein the radiator radiates light as the measurement wave, and
the detector is a camera configured to image the functional member irradiated with the light.

3. The information collection system of claim 2,
wherein the light radiated from the radiator is band-shaped light,
the band-shaped light extends along the bottom surface in a direction intersecting a direction in which the light from the radiator propagates, and
the calculator specifies, from an image taken by the camera, an irradiation position of the band-shaped light on the functional member, and acquires the information on the distance between the main body and the functional member based on information indicating the specified irradiation position.

4. The information collection system of claim 3,
wherein the calculator acquires the information on the distance between the main body and the functional member based on a model representing a relationship between the irradiation position of the band-shaped light on the functional member and the distance between the main body and the functional member.

5. The information collection system of claim 3,
wherein the calculator specifies the irradiation position of the band-shaped light on the functional member within a preset partial range of the image.

6. The information collection system of claim 3,
wherein the calculator specifies, from the image, a position of a boundary between a portion irradiated with the light and a portion not irradiated with the light in a second direction, which is along the bottom surface and is perpendicular to a first direction in which the light from the radiator propagates, and specifies the irradiation position of the band-shaped light on the functional member within a partial range of the image which is apart from the boundary specified in the second direction by a preset amount.

7. The information collection system of claim 3,
wherein the calculator specifies, from the image, the irradiation position of the band-shaped light on the functional member both in a first direction in which the light from the radiator propagates and a second direction which is along the bottom surface and is perpendicular to the direction in which the light from the radiator propagates in a plan view, and acquires the information on the distance between the main body and the functional member based on information indicating the irradiation position specified in each of the first direction and the second direction.

8. The information collection system of claim 1,
wherein the functional member is formed in an annular shape,
the functional member is provided with a protrusion serving to suppress a processing liquid supplied to the substrate from reaching a rear surface of the substrate, and
the distance between the main body and the functional member is a distance between the main body and the protrusion.

9. The information collection system of claim 1,
wherein the functional member is formed in an annular shape, and
the calculator acquires the distance between the main body and the functional member based on the response at each of multiple measurement points located at mutually different positions in a circumferential direction.

10. The information collection system of claim 1,
wherein the main body is provided with a through hole,
the radiator radiates the measurement wave to the functional member through the through hole, and the detector detects the response through the through hole, and
wherein the information collection system further comprises a cover member configured to cover at least the through hole.

11. An inspection substrate configured to acquire information on a substrate processing apparatus including a holder configured to hold a substrate and a functional member located on a rear surface side of the substrate when the substrate is held by the holder, the inspection substrate comprising:
a main body having a bottom surface allowed to be held by the holder;
a radiator fixed to the main body, and configured to radiate a measurement wave to the functional member from obliquely above; and
a detector fixed to the main body, and configured to detect a response resulting from a radiation of the measurement wave from the radiator.

12. The inspection substrate of claim 11, further comprising:
a calculator configured to acquire information on a distance between the main body and the functional member based on the response detected by the detector.

13. An information collection method of acquiring information on a substrate processing apparatus having a holder configured to hold a substrate and a functional member located on a rear surface side of the substrate when the substrate is held by the holder, the information collection method comprising:
holding a bottom surface of a main body with the holder;
radiating a measurement wave from a radiator fixed to the main body to the functional member from obliquely above;
detecting a response resulting from a radiation of the measurement wave from the radiator by a detector fixed to the main body; and
acquiring information on a distance between the main body and the functional member based on the response detected by the detector.

14. The information collection method of claim 13,
wherein in the radiating, the radiator radiates light as the measurement wave, and
the detector is a camera configured to image the functional member irradiated with the light.

15. The information collection method of claim 14,
wherein in the radiating, the light radiated from the radiator is band-shaped light,
the band-shaped light extends along the bottom surface in a direction intersecting a direction in which the light from the radiator propagates, and
in the acquiring, an irradiation position of the band-shaped light on the functional member is specified from an image taken by the camera, and the information on the distance between the main body and the functional member is acquired based on information indicating the specified irradiation position.

16. The information collection method of claim 13,
wherein the functional member is formed in an annular shape,
the functional member is provided with a protrusion serving to suppress a processing liquid supplied to the substrate from reaching a rear surface of the substrate, and
in the acquiring, a distance between the main body and the protrusion is acquired as the information on the distance between the main body and the functional member.
